(19) United States
(12) Patent Application Publication
(10) Pub. No.: US 2005/0168275 A1
(43) Pub. Date: Aug. 4, 2005

(54) Common mode feedback in high speed differential output circuits

(76) Inventors: Hector Torres, McKinney, TX (US); Mark W. Morgan, Allex, TX (US); Allan Stephen Bass, Plano, TX (US)

Correspondence Address: TEXAS INSTRUMENTS INCORPORATED, P O BOX 655474, M/S 3999, DALLAS, TX, 75265, US

(21) Appl. No.: 10/903,459

(22) Filed: Jul. 30, 2004

Related U.S. Application Data
(60) Provisional application No. 60/532,332, filed on Dec. 22, 2003.

(51) Int. Cl. H03K 5/22

(52) U.S. Cl. 327/563

(57) ABSTRACT

A driver circuit comprises a driver portion, differential voltage input terminals, feedback circuitry, and differential voltage output terminals. The feedback circuitry connects a sample portion of the driver portion to a mixer portion of the driver portion. The sample portion may comprise an internal connection to the driver portion, for example, at a midpoint between differential outputs by the driver portion before regulation of the same differential voltages.

### CROSS REFERENCE TO RELATED APPLICATIONS

N/A

### STATEMENT REGARDING FEDERALLY SPONSORED RESEARCH OR DEVELOPMENT

N/A

### BACKGROUND OF THE INVENTION

The present invention is related to systems involved in high speed data transmission. In some aspects, the invention is related to low voltage differential signaling (LVDS) systems, including fully differential multi-channel repeaters, and drivers therefor.

LVDS is becoming a common choice for high speed data transmission. In many cases, high speed data transmission systems use fully differential multi-channel LVDS repeaters. These repeaters are presented with challenging requirements for both skew and speed, similar to the requirements presented to a clock distribution network. These devices are capable of high speed data transmission, yet they may still encounter difficulties if they become subject to capacitive loads much higher than a typical AC load.

FIG. 1 is a block diagram illustrating a common fully differential LVDS repeater 10. Repeater 10 comprises a receiver 14 connected to a driver 16. Receiver 14 senses an input signal Vᵢₙ and drives the driver 16, which produces a differential output voltage Vₒᵤₜ across a resistive load R_{load}.

FIG. 2 is a schematic diagram of a background driver circuit 20 of a fully differential LVDS repeater 10 as shown in FIG. 1. In the illustrated circuit 20, a differential amplifier 22 is provided which comprises input terminals A and B for receiving an input voltage Vᵢₙ′. The illustrated differential amplifier 22 comprises a symmetrical emitter-coupled differential amplifier, comprising a first transistor Q8 (an NPN bipolar junction transistor in the illustrated embodiment) and a second transistor element Q7 (also an NPN bipolar junction transistor).

The collectors of the first and second transistor elements Q8 and Q7 are connected to respective pull-up resistors R6 and R7. Pull-up resistors R6 and R7 are connected at their opposite ends to a common drain of a third transistor element MP2. In the illustrated embodiment, third transistor element MP2 comprises a p-type MOSFET transistor. The source of third transistor element MP2 is connected to a reference voltage Vcc. In the illustrated circuit, third transistor element MP2 serves as a comparator or mixer input for a feedback loop of the illustrated driver.

The respective outputs of differential amplifier 22 are connected to the bases of fourth and fifth transistor elements Q5 and Q6. Fourth and fifth transistor elements Q5 and Q6 serve as voltage drivers 30 and 32, for common mode regulation. The resulting differentially amplified output signal Vₒᵤₜ, is across these Z and Y terminals. The output signal is sampled at the common node 34 of resistors R4 and R5, by a sixth transistor element MN1.

A first constant current source 24 is connected between the common emitter coupling of differential amplifier 22 and ground via a resistor R0. A second constant current source 26 is connected between the first output terminal Z and ground via a resistor R2. A third constant current source 28 is connected between the second output terminal Y and ground via a resistor R3. Each of the constant current sources 24, 26, and 28 comprises an NPN bipolar junction transistor configured as a common-emitter, comprising an input direct current bias voltage Vbbias coupled to the base of each transistor element.

Output resistors R4 and R5 are connected in series across output terminals Z and Y. The common connection between output resistors R4 and R5 may be referred to as a sampling node 34. Feedback circuitry 40 is provided, coupled between sampling node 34, which serves as a feedback sensing point, and a mixing point 36, which is a common connection between pull up resistors R6 and R7 of differential amplifier 22. In the illustrated embodiment, feedback circuitry 40 comprises a resistor R8 and capacitor C8 connected in series between sampling node 34 and ground, and further comprises a number of transistor elements MN0, MN1, MN2, MP0, MP1, and MP2. In the illustrated circuit, transistor elements MN1, MN0, and MN2 comprise n-type MOSFET transistors, and transistor elements MP0, MP1, and MP2 comprise p-type MOSFET transistors.

When the driver illustrated in FIG. 2 is loaded with a single ended capacitance from either output node Z or Y to ground in excess of 10 pF, the illustrated driver's output common mode feedback may become unstable. The illustrated common feedback loop 40 will have essentially two dominant poles, one between MP1 and MN2, and the other between MP2 and resistors R6 and R7. For circuit stability, it is desirable that the poles from the output followers Q5 and Q6 are high enough in the frequency domain, so that they do not interact with the noted pair of dominant poles. This only holds true if the capacitance of the driver load is relatively low.

As the load capacitance is increased, the available bandwidth of the followers Q5 and Q6 will be reduced, bringing the poles of those followers closer in frequency so that they interact with the poles of MP1 and MP2. This can create problems in certain applications, where the capacitance at the output can be difficult to predict.

FIG. 3 shows waveforms representing the magnitude and phase of the closed loop AC voltage response at output sample node 34 of the circuit shown in FIG. 2. The illustrated waveforms show excessive peaking when a 50 pF capacitor is tied between one of the outputs Z and Y of the illustrated circuit and ground. The upper waveform in FIG. 3 illustrates the magnitude in dBs in relation to frequency. The lower waveform shows the phase in degrees in relation to frequency.

### SUMMARY OF THE INVENTION

There is a need for improved common mode feedback approaches in high speed differential outputs circuits, such as drivers used in low voltage differential signaling (LVDS) systems. For example, a driver for an LVDS repeater may become unstable when its load capacitance increases beyond a given level. To alleviate this problem, the sensing point for the driver's feedback loop is moved to a point internal to the driver circuitry.

In accordance with one embodiment of the present invention, a driver circuit is provided for an LVDS repeater. The driver comprises differential voltage input terminals, a driver portion to produce initial differential output voltages, and differential voltage output terminals. The driver portion comprises a differential amplifier. Feedback circuitry connects a sample portion of the driver portion to a mixer portion of the driver portion. The sample portion comprises a connection at a midpoint between the initial differential output of the driver portion.

### BRIEF DESCRIPTION OF THE DRAWINGS

The invention will be more fully understood with reference to the following Detailed Description of the Invention in conjunction with the drawings, of which:

FIG. 1 is a block diagram of a background low voltage differential signaling (LVDS) repeater;

FIG. 2 is a schematic diagram of a background driver circuit;

FIG. 3 shows waveforms representing the closed loop AC response of the feedback loop of the circuit shown in FIG. 2;

FIG. 4 is a schematic diagram of a driver circuit in accordance with one embodiment of the invention;

FIG. 5 shows waveforms representing the closed loop AC response of the feedback loop of the circuit shown in FIG. 4; and

FIG. 6 is a schematic diagram of a driver circuit in accordance with another embodiment of the present invention.

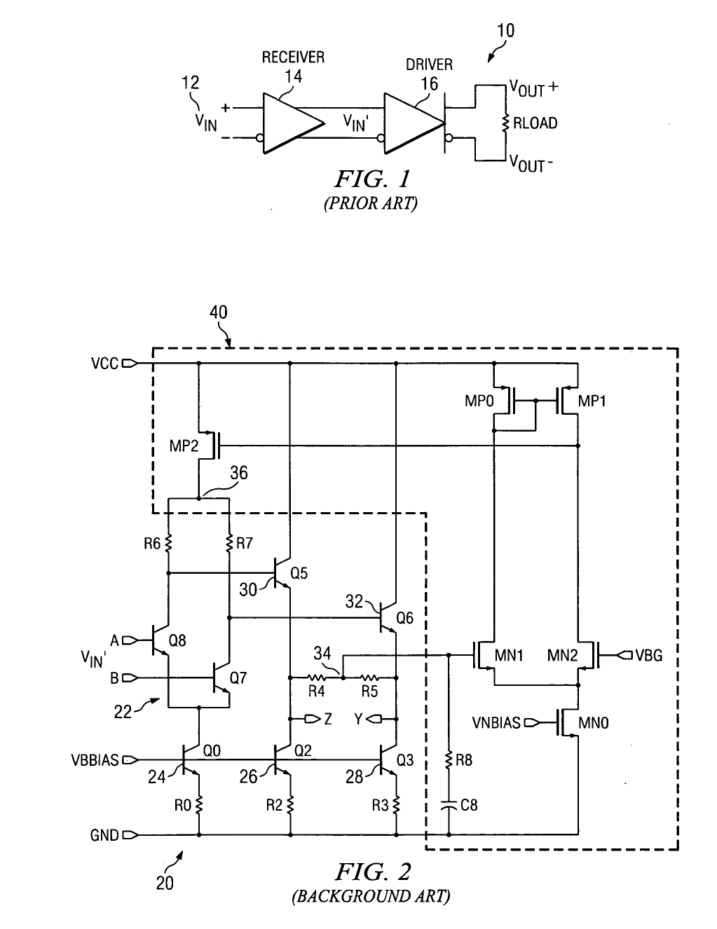

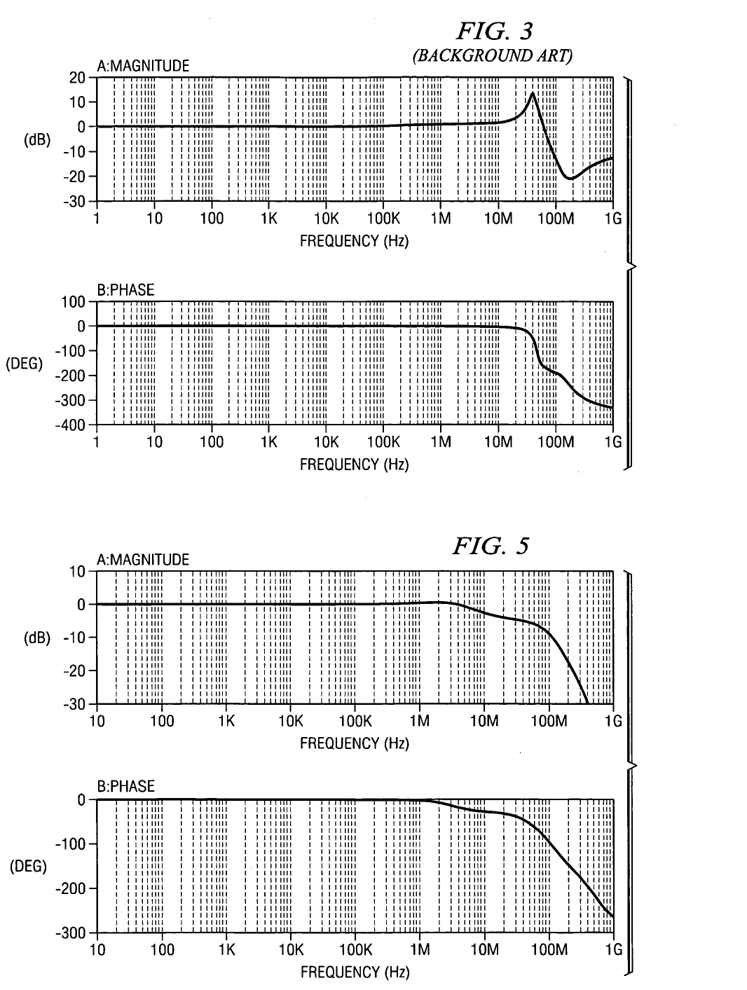

### DETAILED DESCRIPTION

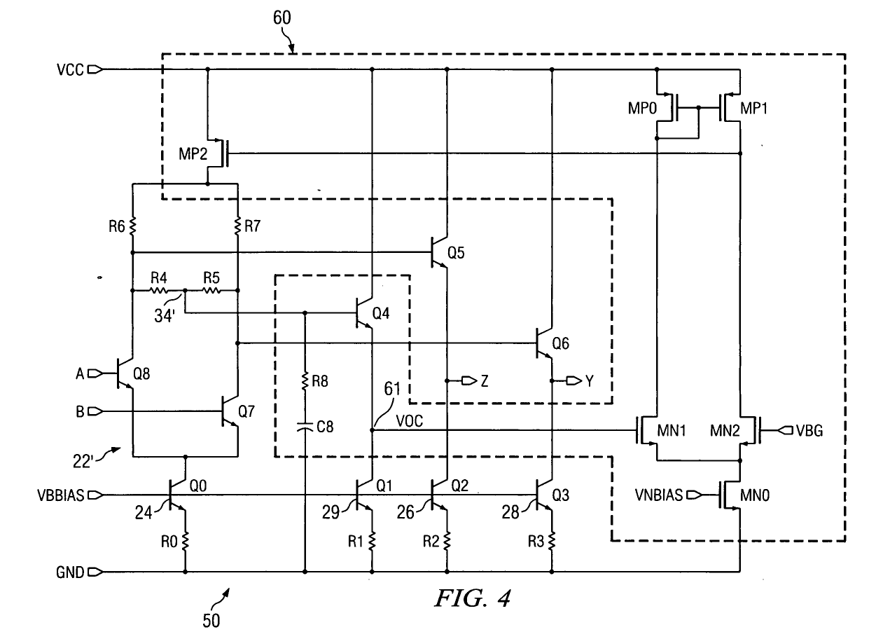

FIG. 4 is a schematic diagram of a driver circuit 50 in accordance with one embodiment of the present invention. In the illustrated driver circuit 50, various elements of the circuit with the same alphanumeric references are the same as the corresponding elements shown in the circuit of FIG. 2, except as follows. Sampling string resistive elements R4′ and R5′ are now connected across the collectors of the first and second transistor elements of the differential amplifier 22′. A sampling node 34′ is formed between the connections of the sampling string of resistive elements R4′ and R5′. The resistor and capacitor R8 and C8 are now coupled between the relocated sampling node 34′ and ground. The base of an additional transistor element Q4 is connected to sampling node 34′. Its collector is connected to the reference voltage Vcc, and its emitter is connected to an additional constant current source 29. Additional constant current source 29 comprises a transistor element Q1, the base of which is connected to the bias DC voltage Vbbias. The collector of transistor Q1 is connected to the emitter of transistor Q4. The emitter of transistor Q1 is connected to a resistor R1, the other end of which is connected to ground. The connection between the emitter of transistor Q4 and the collector of transistor Q1 is the output node 61, which is connected to the drain of the first transistor element MN1 of the feedback circuitry 60.

Feedback circuitry 60 is substantially the same as feedback circuitry 40 in the circuit illustrated in FIG. 2. Specifically, it comprises MOSFETs MN0, MN1, MN2, MP0, MP1, and MP2. Transistors MN0, MN1, and MN2 comprise n type MOSFETs. Transistors MP0, MP1, and MP2 comprise p type MOSFETs. As is the case in the circuit illustrated in FIG. 2, the drain of the first transistor MN0 of the feedback circuitry is connected to a DC bias voltage vnbias. The drain of a second transistor element of the illustrated feedback circuitry MN2 is connected to a band gap reference voltage. In the illustrated embodiment, the band gap reference voltage Vbg is equal to 1.2V.

In the driver circuit 50 shown in FIG. 4, feedback circuitry 60 serves as a common mode feedback loop. The sensing point of the loop originates at sampling node 34′ resulting in a feedback voltage voc input to transistor element MN1. This movement of the sensing point to a position internal to the driver greatly improves the stability of the output voltage across terminals Z and Y. When large capacitances are applied between those output terminals and ground, the output feedback response remains essentially the same. This is demonstrated in the waveforms shown in FIG. 5, which represent the magnitude and phase of the voltage at output node 61 in relation to frequency.

For better performance in common mode regulation, it is beneficial to have transistor Q4 with the same current density as that of transistor elements Q5 and Q6, so the voltage from the base to the emitter of each of these transistor elements (Vbe) will better track over a PVT (performance verification test).

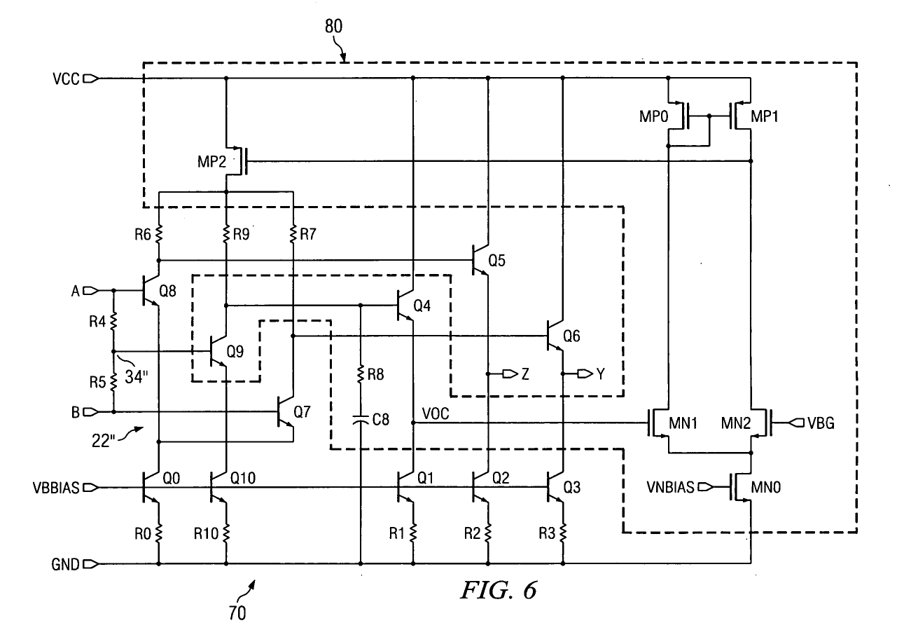

Switching performance will be improved if the driver sampling string resistors R4 and R5 are carefully chosen so as to minimize any parasitic capacitance effect caused thereby. Accordingly, a modified driver circuit may be provided, as shown in FIG. 6. FIG. 6 is a schematic diagram of a driver circuit 70, comprising feedback circuitry 80. Each of the elements of the circuit shown in FIG. 6 are as shown and described above in the circuit of FIG. 4, with the exception of the following. Specifically, driver circuit 70 of FIG. 6 includes an additional pull-up resistor R9, a drive transistor element Q9, a constant current source transistor element Q10, and a resistor element R10. Transistor Q9 is connected at its collector to resistor R9, and at its emitter to transistor Q10. The base of transistor Q9 is connected to sampling node 34″. The sampling node 34″ is formed at the intersection of resistors R4 and R5 which are across the input nodes A and B of differential amplifier 22″.

The value of resistor R9 is equal to the value of resistor R7, which is equal to the value of resistor R6. The collector current of transistor Q10 is half the collector current of transistor Q0. This provides for good tracking and matching over PVT. This implementation also results in a reduced slowdown of the output driver switching speed.

It will also be appreciated by those of ordinary skill in the art that modifications to and variations of the above-described system and method may be made without departing from the inventive concepts disclosed herein. Accordingly, the invention should not be viewed as limited except as by the scope and spirit of the appended claims.

1. A driver circuit comprising:
differential voltage input terminals;
a driver portion comprising a differential amplifier, a sample portion, and a mixer portion;
feedback circuitry connecting the sample portion to the mixer portion; and
differential voltage output terminals;
wherein the sample portion has a signal point within the driver portion at which a signal is sensed for use in the feedback circuitry.

2. The driver circuit according to claim 1, wherein the differential amplifier comprises a symmetrical emitter-coupled differential amplifier.

3. The driver circuit according to claim 2, wherein the differential amplifier comprises a common emitter coupled to ground via a constant current source.

4. The driver circuit according to claim 3, wherein the constant current source comprises a transistor element configured to be a constant current source.

5. The driver circuit according to claim 1, wherein the feedback circuitry comprises a feedback network.

6. The driver circuit according to claim 5, wherein the feedback network comprises a network of MOSFET transistor elements.

7. The driver circuit according to claim 6, wherein the MOSFET transistor elements comprise n and p type transistor elements.

8. The driver circuit according to claim 5, wherein the sample portion comprises a sample node of the driver portion.

9. The driver circuit according to claim 1, wherein the driver portion further comprises voltage regulators to regulate differential voltage output values of the differential amplifier.

10. The driver circuit according to claim 9, wherein the voltage regulators comprise a pair of voltage regulators.

11. The driver circuit according to claim 10, wherein the differential voltage output terminals comprise outputs of the voltage regulators.

12. The driver circuit according to claim 9, wherein the sample portion comprises a portion of the driver portion for sampling a voltage proportional to the mid-point between the differential voltages output by the driver portion before regulation of the differential voltage by the voltage regulators.

13. The driver circuit according to claim 12, wherein the sample portion comprises a sample node between a pair of sample string resistors connected across the differential voltage output by the driver portion before regulation of the differential voltage by the voltage regulators.

14. The driver circuit according to claim 13, wherein the feedback circuitry comprises sample feedback circuitry comprising a base of a sample amplification transistor.

15. The driver circuit according to claim 14, wherein the sample amplification transistor comprises a common emitter amplifier.

16. The driver circuit according to claim 15, wherein the feedback circuitry further comprises circuitry to regulate the voltages output by the sample amplification transistor before the feedback signal is input to the feedback network.

17. The driver circuit according to claim 16, wherein the feedback circuitry further comprises a resistor and capacitor connected in tandem between the sample node and ground.

18. The driver circuit according to claim 16, further comprising a constant current source connected between the emitter of the sample amplification transistor and ground.

19. A driver circuit for driving a signal of a low voltage differential signalling (LVDS) repeater, the circuit comprising:
differential voltage input terminals to receive a differential voltage input;
a driver portion to drive an initial input from the differential voltage input terminals to remaining portions of the driver circuit, the driver portion comprising a differential amplifier, a sample portion from which a signal can be sampled based on the initial input, and a mixer portion into which a feedback signal is fed;
feedback circuitry connecting the sample portion to the mixer portion; and
differential voltage output terminals.
